(19) United States
(12) Patent Application Publication
(10) Pub. No.: US 2023/0369853 A1
(43) Pub. Date: Nov. 16, 2023

(54) CONTROL METHOD, AND CONTROL SYSTEM FOR A SUBSTATION

(71) Applicant: ABB Schweiz AG, Baden (CH)

(72) Inventors: Robert René Maria BIRKE, Kilchberg (CH); Sandro SCHOENBORN, Basel (CH); Thanikesavan SIVANTHI, Würenlingen (CH); Petri HOVILA, Vaasa (FI)

(21) Appl. No.: 18/195,889

(22) Filed: May 10, 2023

(30) Foreign Application Priority Data
May 12, 2022 (EP) 22173037.7

(51) Int. Cl. H02J 3/00; H02J 13/00

(52) U.S. Cl. CPC H02J 3/0012; H02J 13/00034

(57) ABSTRACT

A technique for a control method and a control system in a substation is provided. The control system includes a substation feeder, an intelligent electronic device, IED, a merging unit, and BUS network connecting the IED and the merging unit. The control method includes providing measurement signals by the substation feeder to the merging unit, transmitting, by the merging unit, measurement data based on the measurement signals of the substation feeder to the IED via the BUS network, identifying, by the IED, a fault condition based on the measurement data, transmitting, by the IED, a conditional control command to the merging unit via the BUS network, determining, by the merging unit, whether the condition of the conditional control command is met, and if so initiating, by the merging unit, the control measure of the substation feeder circuit.

### CROSS REFERENCE TO RELATED APPLICATIONS

This patent application claims the benefit and priority of European Patent Application No. 22173037.7 filed on May 12, 2022, the disclosure of which is incorporated by reference herein in its entirety as part of the present application.

### BACKGROUND

The disclosure generally relates to a control method for a control system in a substation, and a control system for a substation.

As automation of substations is advancing, measures for reliable fault identification and troubleshooting are vital. Besides reliability, swiftness of troubleshooting also plays an important role as it has been observed that reaction time has an immediate effect on device equipment and supply security, reaction time referring to the time period between fault occurrence and fault clearance. For instance, overcurrents can build up while a fault occurs, such as a short-circuit, until the fault is resolved by troubleshooting. Thus, length of reaction time has an immediate effect on the magnitude overcurrents build up to. Accordingly, reducing the reaction time for troubleshooting limits the current magnitude.

Device equipment for fault isolation and restoration, such as switchgear, needs to be adapted to resist respective overcurrent magnitudes. Consequently, by reducing reaction time, existing device equipment can be preserved while new equipment can be developed to resist smaller overcurrents, thereby reducing equipment size and costs.

According to the conventional technology, for example, a central protection device is provided within a substation. The device centralizes all protection and control functionality into a single entity on the substation level which allows for a cost-efficient operation. The protection device complies with standardized requirements, e.g. IEC 61850, that define communication protocols between the protection device and equipment located within the substation. The requirements also define a reaction time, i.e. one-way delay, which must not be exceeded when communicating a control command for troubleshooting. It is, however, favorable to further reduce the reaction time for preserving existing equipment, thereby extending its lifetime, and also for development of new equipment.

### BRIEF DESCRIPTION

An aspect of the present disclosure provides a control method. The control method is configured for a control system in a substation. The control system includes a substation feeder, an intelligent electronic device, IED, a merging unit, and BUS network which connects the IED and the merging unit. The control method includes providing measurement signals by the substation feeder to the merging unit. Further, the method includes transmitting, by the merging unit, measurement data based on the measurement signals of the substation feeder to the IED via the BUS network, and identifying, by the IED, a fault condition based on the measurement data, the fault condition being indicative of an actual or potentially forthcoming fault. The method also includes transmitting, by the IED, a conditional control command to the merging unit via the BUS network, the conditional control command including a control measure and a condition for executing the control measure, determining, by the merging unit, whether the condition of the conditional control command is met, and if so initiating, by the merging unit, the control measure of the substation feeder circuit.

An IED, as used herein, refers to a real-time protection and control entity of a substation. A substation may have multiple decentralized IEDs, or a single, centralized IED. In the latter case, the IED benefits from a more global view spanning multiple/all merging units, while also providing substation-wide visibility. Yet, a centralized IED forfeits proximity to the sensors and switchgear bay of feeders which implies longer decision paths, including both communication and decision logic, and thereby reaction times.

The IED may provide a human-machine interface (HMI) for input by a user and displaying and/or providing data to a user. The IED may also allow for disturbance recordings for the entire substation. The IED typically receives measurement data from the merging unit via the BUS network. It includes logic to process the measurement data in order to identify a fault condition and to issue a conditional control command. The logic includes both, hardware components, e.g. a microprocessor, and software components. Besides issuing a conditional control command, the IED may also be configured to issue a control command without a condition that the merging unit executes in any case.

A merging unit, as used herein, refers to an entity which is configured to merging measurement signals from the feeder into measurement data of a standard digital output format. The merging unit may include converting analog measurement signals into digital measurement data. The merging unit may also include sampling the measurement signal and further data processing, such as filtering. The merging unit may provide the measurement data in digital data packets such as IP packets (e.g., TCP/IP packets such as Ethernet frames) for communication over the BUS network. The data packets may be unicast, multicast or broadcast frames.

The BUS network may be an IP packet-based network such as an Ethernet-based network, for instance a local area network (LAN), or internet-based, for instance a wide area network (WAN), the latter using IP in some cases. The BUS Network can also be based on other technologies such as MPLS (Multiprotocol Label Switching).

The condition of the conditional control command typically includes a control decision model based on the measurement data. The decision path between the merging unit and the switchgear bay is generally shorter than between the IED and the switchgear bay. Thus, there may be a reduction in reaction time depending on where the decision model is executed. The decision path may be adapted accordingly, for instance in systems with distributed set-ups or non-local components. Therefore, control models are provided that vary with respect to where parts or the entire control model is executed.

In some embodiments, the control model relies on communication between the IED and the merging unit which complies to a standard communication protocol, such as the IEC 61850 standard for communication and interoperability in the digital substations.

Accordingly, the IED may issue the conditional control command complying to a control model defined as Generic Object Oriented Substation Events (GOOSE) by the IEC 61850. Irrespective of whether or not the conditional command is a GOOSE command, the conditional command may adhere to one or more of the following characteristics of GOOSE: GOOSE requires the IED to transmit the conditional control commands within a typical period of less than 10 milliseconds (e.g., 3 milliseconds or 4 milliseconds) to the merging unit. GOOSE may adhere to a publisher/subscriber model, in which a publisher transmits unacknowledged data to subscribers. In the case of an event, a burst of messages with new data is transmitted thereby minimizing the chance of message loss. As GOOSE-commands are published under a topic, the subscriber, i.e. the merging unit, filters only messages identified by a subscribed topic. A GOOSE command may include, for instance, a specified control measure, such as closing a circuit breaker.

Alternatively, communication between the IED and the merging unit adheres to a hierarchical control model. In some cases, such communication may be implemented as an extension to the above-described GOOSE control model. As an example, a GOOSE command may be provided with a condition specifying under what condition the merging unit is to carry out the GOOSE command. Such an extended GOOSE command may include, for instance, a specified control measure plus a conditional instruction, such as an elapse of a time period to execute the control measure.

The hierarchical control model may further enable the IED to dynamically transmit small pieces of flexible programming code, referred to herein as codelet, over the BUS network and to install such a codelet at the merging unit. Such codelets are configured to be executed at the merging unit. The merging unit processes this codelet to take simple decisions locally. Codelets may include functionalities such as condition-based status updates, if-else decision trees evaluating multiple signals, or even a trained machine learning model. Also, the codelets may provide a potential action to take. The codelets may be generic or tuned to one or more target merging units. As the merging unit is arranged in proximity to the feeder with its sensors and switchgear bay, the decision path and, thereby, the reaction time is reduced. As a result, both benefits, the IED's global view and the short path from the merging units to the switchgear bay are combined. Moreover, delegating tasks to the merging unit also frees the IED from having to take actions at the desired point in time allowing it to process another task. This provides an opportunity for the IED to outsource actions, thereby providing additional processing resources.

The merging unit may provide the measurement data complying to sampled values (SV) or sampled measure values (SMV), the latter being defined by the IEC 61850-9-2 standard. The measurement data may be published by the merging unit at a specific rate for a specific grid frequency, for instance at 4000 frames per second for a grid frequency of 50 Hz and 4800 frames per second for 60 Hz. SMV may adhere to a publisher/subscriber model, in which a publisher transmits unacknowledged data to subscribers.

The merging unit typically offers a physical interface to a switchgear bay of the feeder. The switchgear bay may be configured for executing a control measure initiated by the merging unit. A control measure, as used herein, typically includes an operation, in particular a protective operation, within the substation feeder circuit by the switchgear bay, such as separating a feeder from the substation if the feeder has a fault, or closing a breaker of the substation feeder circuit after a fault is resolved, in particular tripping circuit breakers, or also raising/lowering tap position in order to maintain desired voltage level. The switchgear bay may provide the hardware equipment to execute a respective control measure.

Fault condition being indicative of a potentially forthcoming fault, is used herein to describe anomalies in the measurement data, such as a loss of voltage, overcurrent, or frequency deviation.

In one embodiment, the control system includes at least one second merging unit and at least one second substation feeder. The BUS network connects the IED and the at least one second merging unit. The method further includes providing measurement signals by the at least one second substation feeder to the at least one second merging unit. The method also includes transmitting, by the at least one second merging unit, second measurement data based on the measurement signals of the at least one second substation feeder to the IED via the BUS network.

In this embodiment, the method may further include identifying, by the protection device, a second fault condition based on the second measurement data, the fault condition being indicative of a potentially forthcoming fault, and transmitting, by the protection device, a conditional control command to the at least one second merging unit via the BUS network. This enables the IED to take a more global perspective of multiple substation feeders and to derive therefrom a potential fault condition for a specific substation feeder and to instruct a respective merging unit.

In a further embodiment, transmitting the conditional control command via the BUS network complies with a hierarchical communication protocol. The merging unit is located at a lower hierarchical level than the IED within the hierarchical communication protocol. The measurement data may also be transmitted via the BUS network, according to the hierarchical or to a non-hierarchical communication protocol.

In one embodiment, the control method further includes encoding the condition of the conditional control command in a codelet by the IED and transmitting the codelet by the IED to the merging unit via the BUS network. The method also includes processing the codelet by the merging unit. The merging unit may encompass a codelet interpreter for processing the codelet. For instance, the codelet may include a sequence of instructions that the merging unit executes. Such instructions may include functional statements such as “IF I>100 A, Trip breaker, ENDIF”.

In an alternative embodiment, the condition of the conditional control command includes a specified reaction time period until initiation of the protection measure. Such a “timed” command is issued to execute a specific protection measure after expiration of the set reaction time. Devices in substations are typically synchronized and thereby refer to a common time. Thus, the reaction time of the “timed” command may be calculated based on the common reference frame.

Alternatively or additionally, the condition of the conditional control command includes a specified fault threshold for the measurement data. In some cases, the condition includes a specified fault threshold for the measurement data over a specified time period.

Alternatively or additionally, the condition of the conditional control command includes a zero-crossing condition for a measured current and/or voltage.

Examples for specifying the condition may consider applications such as zero-point switching of a circuit breaker. Thereby, the merging unit may locally determine the moment when to initiate the control action, that is when an alternating current of the feeder passes through zero. That way, potential switching arcs and other hazards are prevented.

The measurement signals typically include at least one of a voltage signals, current signals, temperature signals, and frequency signals. The measurement data typically includes at least one of a current data, voltage data, and frequency data based on the respective measurement signals.

In another embodiment, the control measure further includes operating at least one switchgear bay of the substation. The switchgear bay may include at least one of a circuit breaker, a disconnector, load switch or switch disconnector. The switch disconnector may include common switch disconnectors or fuse switch disconnectors. The operating may include a control action.

In yet another embodiment, the control method further includes identifying, by the IED, a no-fault condition based on the measurement data, the no-fault condition being indicative of the conditional control command being no longer necessary, and transmitting, by the IED, a cancel command for cancelling the conditional control command to the merging unit.

Another aspect of the present disclosure provides a merging unit for a control system for a substation. The merging unit includes a feeder-facing interface for receiving the measurement signals from at least one substation feeder. The merging unit also includes a signal converter for providing measurement data based on the measurement signals of the at least one substation feeder. Further, the merging unit has a BUS interface for transmitting the measurement data via a BUS network to an IED and for receiving a conditional control command from the IED. The conditional control command includes a control measure and a condition for executing the control measure. The merging unit also includes logic configured for determining whether the condition of the conditional control command is met, and if so, for initiating the control measure of the substation feeder circuit.

A further aspect of the present disclosure provides a control system for a substation. The control system includes at least one substation feeder with sensors for providing measurement signals, at least one merging unit, an IED, and a BUS network. The BUS network connects the at least one merging unit with the IED. The at least one merging unit has a feeder-facing interface for receiving the measurement signals from the at least one substation feeder, a signal converter for providing measurement data based on the measurement signals of the at least one substation feeder, and a BUS interface for transmitting the measurement data via the BUS network to the IED. The IED has a BUS interface for receiving the measurement data. The IED has also logic for identifying, based on the measurement data, a fault condition indicative of a potentially forthcoming fault and for providing a conditional control command. The BUS interface is configured for transmitting the conditional control command via the BUS network to the at least one merging unit. The conditional control command includes a control measure and a condition for executing the control measure. The merging unit has logic configured for determining whether the condition of the conditional control command is met, and if so, for initiating the control measure of the substation feeder circuit.

Further features are derivable from the dependent claims.

In an embodiment, the BUS network between the IED and the merging unit complies with a hierarchical communication protocol. The at least one merging unit is located at a lower hierarchical level than the IED within the hierarchical communication protocol.

In an alternative embodiment, the conditional control command is encoded as a codelet, and the merging unit has logic configured for carrying out the codelet. The codelet may be precompiled or created on the fly by the IED. The codelet may be generic or targeting a specific merging unit or a group of merging units. The codelet may encompass functional statements, a compute graph, or machine learning model used to take the decision on a control action.

In yet another embodiment, the control system further includes at least one switchgear bay. The switchgear bay may include at least one of a circuit breaker, a disconnector, load switch, or switch disconnector. The control measure may include a control action. The circuit breaker may be a gas-insulated or an air-insulated circuit breaker. The switchgear system may be configured for low voltage (up to, e.g., 1 KV), medium voltage (e.g., 3 KV to 36 KV) or high voltage (e.g., above 36 KV). The switchgear may use communication standards which are different from the IEC 61850 standard, for instance OPC-UA, MODBUS, IEC 60870, DNP3. These standards may be extended to carry a conditional control command and/or a codelet.

The control system is further configured for carrying out above-described method or parts thereof.

### BRIEF DESCRIPTION OF THE DRAWINGS

FIG. 1 illustrates a schematic diagram of a control method for a control system in a substation according to an embodiment of the present disclosure;

FIG. 2 illustrates a schematic diagram of a BUS network of a substation complying with a hierarchical communication protocol according to an embodiment of the present disclosure; and

FIG. 3 illustrates a schematic circuit diagram of a control system for a substation according to embodiments of the present disclosure.

### DETAILED DESCRIPTION

In the following, embodiments are set forth to describe specific examples presented herein. The person skilled in the art will recognize that one or more other examples and/or variations of these examples may be practiced without all the specific details outlined below. Also, well known features may not be described in detail so as not to obscure the description of the examples herein. For the ease of illustration, like reference numerals are used in different figures to refer to the same elements or additional instances of the same element.

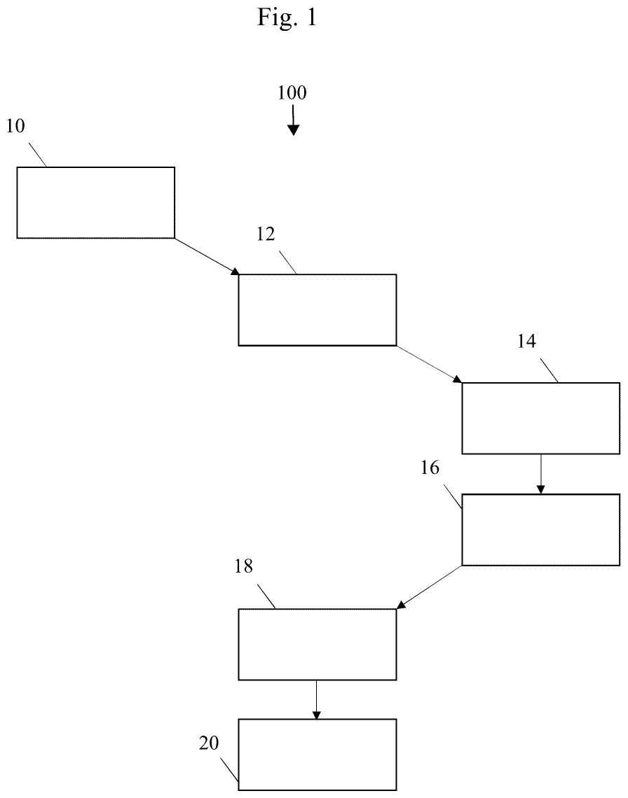

Referring now to the drawings, FIG. 1 illustrates a control method 100 for a control system in a substation. The control system and its components which include a substation feeder, an intelligent electronic device, IED, a merging unit, and BUS network connecting the IED and the merging unit are described in more detail with reference to FIG. 3 below. FIG. 1 with its horizontal arrangement of boxes is intended to illustrate the control system's component carrying out the respective method step. Thereby, the method step symbolized by the box furthest left is carried out by a substation feeder; the method steps symbolized by the middle boxes are carried out by the merging unit; while the method steps symbolized by the boxed furthest right are carried out by the IED.

The control method 100 includes providing measurement signals 10 by the substation feeder to the merging unit. In step 12, the method provides for transmitting, by the merging unit, measurement data based on the measurement signals of the substation feeder to the IED via the BUS network. Next, the method foresees identifying 14, by the IED, a fault condition based on the measurement data, the fault condition being indicative of a potentially forthcoming fault, and transmitting 16, by the IED, a conditional control command to the merging unit via the BUS network 38a, 38b, the conditional control command including a control measure and a condition for executing the control measure. Lastly control method 100 provides for determining 18, by the merging unit, whether the condition of the conditional control command is met, and if so initiating 20, by the merging unit, the control measure of the substation feeder circuit.

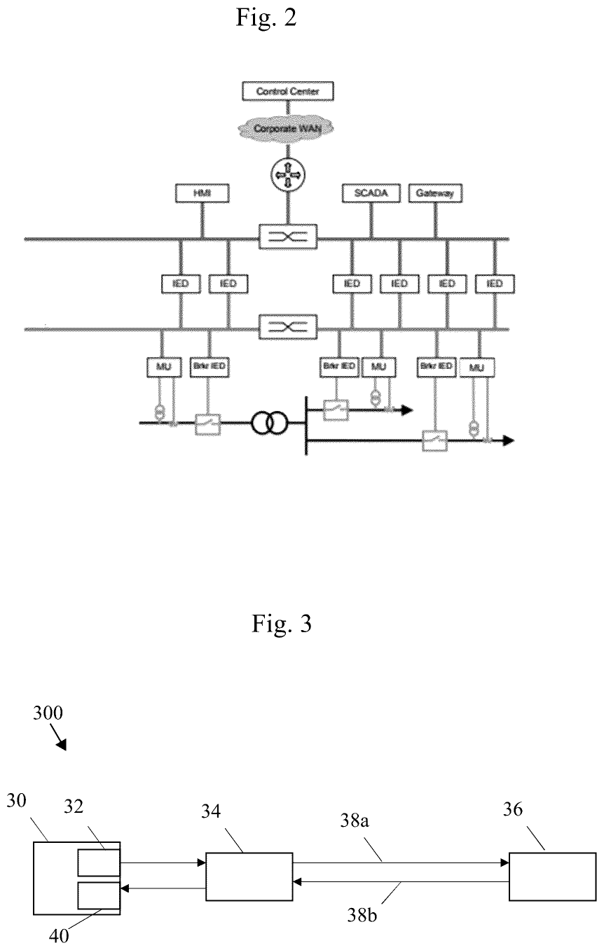

Referring now to FIG. 2, a schematic diagram of a BUS network of a substation complying with a hierarchical communication protocol according to an embodiment of the present disclosure is illustrated. As shown, the hierarchical communication protocol connects different levels, with the merging units MU being allocated at a lower level and the IED being allocated at a higher level. Lastly, a human-machine interface HMI, supervisory control and data acquisition SCADA and/or gateway are allocated at the highest level. Although multiple IED are shown, some embodiments may provide for a single, centralized IED within entire substation. In this case, the IED provides for substation-wide visibility. The IED is configured to send and install codelet, via the hierarchical communication protocol, to a single or multiple merging units. The hierarchical communication protocol can be an extension to above-described GOOSE model, or any other suitable hierarchical protocol.

Referring now to FIG. 3, a schematic circuit diagram of a control system 300 for a substation according to the present disclosure is illustrated. The components of control system 300 include a substation feeder 30 with sensors 32 for providing measurement signals and a switchgear bay 40 for operating a control action. The switchgear bay is configured for operating a control action, such as to separate the feeder 30 from the substation if the feeder 30 is faulted. Likewise, the switchgear bay can close a breaker after a fault is resolved.

The control system 300 further includes a merging unit 34, an IED 36, and a BUS network 38a, 38b. Although only one merging unit is displayed, the principles described herein apply equally to a control system with more than one merging unit. The BUS network 38a, 38b connects the merging unit 34 with the IED 36. The BUS network provides for two connections 38a and 38b. Connection 38a serves for transmitting the measurement data, in some cases complying with SMV, to the IED 36, while connection 38b serves for transmitting the conditional control command to the merging unit by the IED, the conditional control command including a control measure and a condition for executing the control measure. In some cases, connection 38b complies with GOOSE, in other cases connection 38b complies with an extension to GOOSE such that a hierarchical communication protocol between the IED 36 and the merging unit 34 is established, in yet other cases, connection 38b complies to a hierarchical communication protocol irrespective of GOOSE.

Interfaces of the merging unit 34 and the IED 36 are not illustrated with separate reference sign for reasons of clarity, but are located at the arrows' endpoints, respectively. In particular, the merging unit 34 has a feeder-facing interface for receiving the measurement signals from the sensors 32 of the substation feeder 30 and for initiating control measure by the switchgear by 40. To connect to the BUS network, the merging unit 34 has a BUS interface for transmitting the measurement data via the BUS network to the IED 36 and for receiving the conditional control commands by the IED. The IED 36 also has a BUS interface for receiving the measurement data and for transmitting the conditional control command via the BUS network to the merging unit 34.

Embodiments and/or features described herein with respect to the control method may be implemented equally within the control system and vice versa.

1. A control method for a control system in a substation, the control system comprising a substation feeder, an intelligent electronic device (IED) a merging unit, and a Binary Unit System (BUS) network connecting the IED and the merging unit, the control method comprising:
providing measurement signals by the substation feeder to the merging unit;
transmitting, by the merging unit, measurement data based on the measurement signals of the substation feeder to the IED via the BUS network;
identifying, by the IED, a fault condition based on the measurement data, the fault condition being indicative of a potentially forthcoming fault;
transmitting, by the IED, a conditional control command to the merging unit via the BUS network, the conditional control command comprising a control measure and a condition for executing the control measure;
determining, by the merging unit, whether the condition of the conditional control command is met; and if so
initiating, by the merging unit, the control measure of a substation feeder circuit.

2. The control method of claim 1, wherein the control system comprises at least one second merging unit and at least one second substation feeder, the BUS network connecting the IED and the at least one second merging unit, the method further comprising:
providing measurement signals by the at least one second substation feeder to the at least one second merging unit; and
transmitting, by the at least one second merging unit, second measurement data based on the measurement signals of the at least one second substation feeder to the IED via the BUS network.

3. The control method of claim 1, wherein transmitting the conditional control command via the BUS network complies with a hierarchical communication protocol, and wherein the merging unit is located at a lower hierarchical level than the IED within the hierarchical communication protocol.

4. The control method of claim 1, further comprising:
encoding the condition of the conditional control command in a codelet by the IED and transmitting the codelet by the IED to the merging unit via the BUS network; and
processing the codelet by the merging unit.

5. The control method of claim 1, wherein the condition of the conditional control command comprises a specified reaction time period until initiation of a protection measure.

6. The control method of claim 1, wherein the condition of the conditional control command comprises a specified fault threshold for the measurement data.

7. The control method of claim 1, wherein the condition of the conditional control command comprises a control decision model based on measurement data, the control decision model comprising a zero-crossing condition for a measured current and/or voltage.

8. The control method of claim 1, wherein the measurement signals comprise at least one of a voltage signals, current signals, temperature signals, and frequency signals.

9. The control method of claim 1, wherein the control measure comprises operating at least one switchgear bay of the substation.

10. The control method of claim 1, further comprising
identifying, by the IED, a no-fault condition based on the measurement data, the no-fault condition being indicative of the conditional control command being no longer necessary; and
transmitting, by the IED, a cancel command for cancelling the conditional control command to the merging unit.

11. A merging unit for a control system for a substation, the merging unit comprising:
a feeder-facing interface configured to receive measurement signals from at least one substation feeder of the substation;
a signal converter configured to provide measurement data based on the measurement signals of the at least one substation feeder;
a Binary Unit System (BUS) interface configured to transmit the measurement data via a BUS network to an intelligent electronic device (IED) and to receive a conditional control command from the IED, wherein the conditional control command comprises a control measure and a condition to execute the control measure; and
logic configured to determine whether the condition of the conditional control command is met, and if so, to initiate the control measure of the substation feeder circuit.

12. A control system for a substation, the control system comprising:
at least one substation feeder with sensors configured to provide measurement signals;
at least one merging unit according to claim 11;
an IED; and
a BUS network connecting the at least one merging unit with the IED, wherein
the IED has a BUS interface configured to receive the measurement data; logic configured to identify, based on the measurement data, a fault condition indicative of a potentially forthcoming fault and configured to provide a conditional control command, wherein the BUS interface is configured to transmit the conditional control command via the BUS network to the at least one merging unit.

13. The control system of claim 12, wherein the BUS network between the IED and the merging unit complies with a hierarchical communication protocol, and wherein the at least one merging unit is located at a lower hierarchical level than the IED within the hierarchical communication protocol.

14. The control system of claim 12, wherein the conditional control command is encoded as a codelet, and wherein the merging unit has logic configured to carry out the codelet.

15. The control system of claim 12, further comprising at least one switchgear bay, the switchgear bay comprising at least one of a circuit breaker, a disconnector, a load switch or a switch disconnector, the control measure comprising a control action.

16. The control method of claim 9, wherein the switchgear bay includes at least one of a circuit breaker, a disconnector, a load switch or a switch disconnector, the operating comprising a control action.

17. The control system of claim 13, wherein the conditional control command is encoded as a codelet, and wherein the merging unit has logic configured to carry out the codelet.

18. The control system of 13, further comprising at least one switchgear bay, the switchgear bay comprising at least one of a circuit breaker, a disconnector, a load switch or a switch disconnector, the control measure comprising a control action.

19. The control system of 14, further comprising at least one switchgear bay, the switchgear bay comprising at least one of a circuit breaker, a disconnector, a load switch or a switch disconnector, the control measure comprising a control action.
